(19) United States
(12) Patent Application Publication
(10) Pub. No.: US 2026/0360654 A1
(43) Pub. Date: Nov. 12, 2026

(54) CHARGE NEUTRALIZATION IN CHARGED PARTICLE BEAM APPARATUS USING SOURCE-SIDE ENERGY MODULATION

(71) Applicant: Applied Materials Israel Ltd., Rehovot (IL)

(72) Inventors: Alexander Goldenshtein, Ness Ziona (IL); Albert Karabekov, Ashdod (IL); Dan Tuvia Fuchs, Tel-Aviv (IL)

(73) Assignee: Applied Materials Israel Ltd., Rehovot (IL)

(21) Appl. No.: 19/205,863

(22) Filed: May 12, 2025

(51) Int. Cl. H01J 37/02; H01J 37/147; H01J 37/26

(52) U.S. Cl. CPC H01J 37/026; H01J 37/1471; H01J 37/265; H01J 2237/0473; H01J 2237/20221

(57) ABSTRACT

A charged particle beam apparatus and method are described for imaging a sample and neutralizing accumulated surface charge. The system includes a charged particle source and a control unit configured to switch between imaging and discharge modes by adjusting the accelerating voltage applied to the source. In the discharge mode, the beam reaches the sample with near-zero landing energy, enabling spatially extended and self-limiting neutralization of positive surface charge. The sample remains at ground potential throughout operation. Mode switching can be performed rapidly without modifying the state of the beam-forming optics. Optional enhancements include beam current modulation, field-of-view adjustment, and synchronized scanning during continuous sample motion.

### BACKGROUND OF THE INVENTION

The present invention relates to charged particle beam apparatus, such as scanning electron microscopes or inspection systems, and more particularly to methods and systems for controlling beam energy to facilitate surface charge neutralization.

Charged particle beam systems, including electron beam inspection tools and scanning electron microscopes, are commonly used for high-resolution imaging and measurement of sample surfaces. During operation, particularly when imaging insulating or partially insulating materials, the accumulation of electrical charge on the sample surface can interfere with imaging performance and beam control. Various approaches have been proposed to neutralize surface charge, including the use of low-energy electron beams that interact with the charged regions of the sample.

### BRIEF SUMMARY OF THE INVENTION

The present invention is a charged particle beam apparatus and corresponding method of operation for imaging a sample and neutralizing charge accumulated on the sample.

According to the teachings of an embodiment of the present invention there is provided, a method of operating a charged particle beam apparatus for imaging a sample and neutralizing charge accumulated on the sample, the method comprising: (a) generating a charged particle beam using a charged particle source supplied with an accelerating voltage; (b) directing the charged particle beam along a beam path through one or more beam-forming or focusing elements toward the sample, wherein the sample is positioned on a sample holder maintained at ground potential; (c) operating the apparatus in an imaging mode in which the accelerating voltage is set to a first value such that the charged particle beam reaches the sample with a non-zero landing energy suitable for imaging; and (d) switching the apparatus from the imaging mode to a discharge mode by reducing the accelerating voltage to a second value such that the charged particle beam reaches the sample with a landing energy approximately equal to zero electron volts, thereby enabling charge neutralization, wherein, due to the reduced accelerating voltage in the discharge mode, the charged particle beam diverges in a region adjacent the sample such that a spatially extended area of the sample surface is exposed to the low-energy charged particles for charge neutralization.

According to a further feature of an embodiment of the present invention, the accelerating voltage is modulated by adjusting a potential applied to an electrode of the charged particle source, the electrode having a low capacitance relative to the sample holder.

According to a further feature of an embodiment of the present invention, the electrode forms part of the charged particle source assembly.

According to a further feature of an embodiment of the present invention, a retarding voltage is applied to an electrode located proximate the sample to decelerate the charged particle beam, wherein the retarding voltage remains constant during switching between the imaging mode and the discharge mode.

According to a further feature of an embodiment of the present invention, the charged particle beam comprises electrons and the landing energy in the discharge mode is sufficiently close to zero electron volts that the electrons are reflected from regions of the sample having a local negative surface potential while being attracted to regions of the sample having a local positive surface potential, thereby neutralize accumulated positive charge.

According to a further feature of an embodiment of the present invention, reducing the accelerating voltage in the discharge mode causes the beam to experience increased divergence near the sample surface, thereby achieving spatially distributed charge neutralization over a region greater than an imaging mode beam spot size.

According to a further feature of an embodiment of the present invention, the beam path during the discharge mode is laterally offset from the beam path during the imaging mode, and the divergence of the beam in the discharge mode is sufficient to cause overlap of the neutralization region with the imaging location.

According to a further feature of an embodiment of the present invention, a beam deflection element is modulated in coordination with switching between the imaging mode and the discharge mode so as to maintain alignment of the beam landing position on the sample.

According to a further feature of an embodiment of the present invention, the beam deflection element comprises a final shift or beam steering unit located proximate the sample.

According to a further feature of an embodiment of the present invention, a fixed deflection offset is applied to the charged particle beam path, wherein a native energy-dependent difference in beam landing position is compensated by the energy-dependent sensitivity of a beam deflection element.

According to a further feature of an embodiment of the present invention, the sample holder is moved continuously during operation of the apparatus, and switching between the imaging mode and the discharge mode is performed during such motion.

According to a further feature of an embodiment of the present invention, the position of the charged particle beam is manipulated in synchronization with the movement of the sample holder to provide spatially distributed charge neutralization.

According to a further feature of an embodiment of the present invention, image data is acquired using a scanning frame averaging process that combines image data from overlapping regions to compensate for motion of the sample holder.

According to a further feature of an embodiment of the present invention, switching between the imaging mode and the discharge mode is performed by modulating the accelerating voltage within a time period of less than 100 microseconds, without requiring refocusing of the charged particle beam.

There is also provided according to the teachings of an embodiment of the present invention, a charged particle beam apparatus for imaging a sample and neutralizing charge accumulated on the sample, the apparatus comprising: (a) a charged particle source configured to emit a charged particle beam and to receive an accelerating voltage to control the energy of the emitted beam; (b) a beam delivery system configured to direct the charged particle beam along a beam path through one or more beam-forming or focusing elements toward the sample; (c) a sample holder configured to support the sample and to be maintained at ground potential during operation in the imaging and discharge modes; (d) a control system configured to switch between an imaging mode, in which the accelerating voltage is set to a first value such that the charged particle beam reaches the sample with a non-zero landing energy suitable for imaging, and a discharge mode, in which the accelerating voltage is set to a second value such that the charged particle beam reaches the sample with a landing energy approximately equal to zero electron volts to enable charge neutralization, wherein, due to the reduced accelerating voltage in the discharge mode, the charged particle beam diverges in a region adjacent the sample such that a spatially extended area of the sample surface is exposed to the low-energy charged particles for charge neutralization.

According to a further feature of an embodiment of the present invention, the charged particle source comprises an electrode forming part of a source assembly, and the control system is configured to apply the accelerating voltage to the electrode.

According to a further feature of an embodiment of the present invention, the electrode has a capacitance lower than that of the sample holder, thereby enabling rapid modulation of the accelerating voltage.

According to a further feature of an embodiment of the present invention, there is also provided an electrode located proximate the sample and configured to receive a retarding voltage for decelerating the charged particle beam, wherein the control system is further configured to maintain the retarding voltage constant while switching between the imaging mode and the discharge mode.

According to a further feature of an embodiment of the present invention, the charged particle beam comprises electrons, and wherein in the discharge mode the landing energy is sufficiently close to zero electron volts that the electrons are reflected from regions of the sample having a local negative surface potential.

According to a further feature of an embodiment of the present invention, the beam delivery system is configured such that, in the discharge mode, the charged particle beam diverges near the sample, thereby achieving spatially distributed charge neutralization over a region greater than an imaging mode beam spot size.

According to a further feature of an embodiment of the present invention, the beam path during the discharge mode is laterally offset from the beam path during the imaging mode, and the divergence of the beam in the discharge mode is sufficient to cause overlap of the neutralization region with the imaging location.

According to a further feature of an embodiment of the present invention, there is also provided a beam deflection unit configured to shift the landing position of the charged particle beam, wherein the control system is further configured to adjust the deflection unit in coordination with switching between the imaging mode and the discharge mode to maintain beam alignment.

According to a further feature of an embodiment of the present invention, the beam deflection unit comprises a final shift or beam steering element located proximate the sample.

According to a further feature of an embodiment of the present invention, there is also provided a beam deflection unit configured to apply a fixed deflection offset, wherein a native energy-dependent difference in beam landing position between the imaging mode and the discharge mode is compensated by the energy-dependent deflection sensitivity of the beam deflection unit.

According to a further feature of an embodiment of the present invention, there is also provided a translation stage configured to move the sample holder continuously during operation, wherein the control system is configured to switch between the imaging mode and the discharge mode during such motion.

According to a further feature of an embodiment of the present invention, the control system is configured to adjust the position of the charged particle beam in synchronization with movement of the sample holder to provide spatially distributed charge neutralization.

According to a further feature of an embodiment of the present invention, there is also provided an image acquisition system configured to generate image data using a scanning frame averaging process that combines image data from overlapping regions to compensate for motion of the sample holder.

According to a further feature of an embodiment of the present invention, the control system is configured to switch between the imaging mode and the discharge mode by modulating the accelerating voltage within a time period of less than 100 microseconds, without requiring refocusing of the charged particle beam.

According to a further feature of an embodiment of the present invention, there is also provided an electron detector configured to detect secondary or backscattered electrons emitted from the sample during operation in the imaging mode, and a processing unit configured to generate image data from signals output by the detector.

### BRIEF DESCRIPTION OF THE DRAWINGS

The invention is herein described, by way of example only, with reference to the accompanying drawings, wherein:

FIG. 1 is a schematic diagram of a charged particle beam apparatus according to an embodiment of the invention, showing a charged particle source, beam delivery optics, a control system, a sample holder maintained at ground potential, and optional detection and retarding components;

FIG. 2 is a set of graphs illustrating schematically profiles of electrical potential and electron kinetic energy along the beam axis in an imaging mode and a discharge mode, respectively, illustrating differences in the resulting landing energy at the sample;

FIG. 3 is a schematic isometric view of beam trajectories in the imaging and discharge modes, illustrating differences in beam divergence and spot size at the sample surface;

FIG. 4 is a diagram showing a beam alignment compensation arrangement in which a common deflection is applied to imaging and discharge beams having different energy levels, resulting in aligned beam landing locations;

FIG. 5 is a timing diagram illustrating an example sequence of switching between imaging and discharge modes; and

FIGS. 6A and 6B are schematic side views of a sample surface showing an accumulation of localized charge during operation in an imaging mode and an interaction of low-energy charged particles with regions of localized positive surface charge during operation in a discharge mode, respectively.

### DETAILED DESCRIPTION OF THE INVENTION

The present invention is a charged particle beam apparatus and corresponding method of operation for imaging a sample and neutralizing charge accumulated on the sample. In particular, the invention concerns methods and apparatus for facilitating charge neutralization on the surface of a sample by selectively adjusting the energy of the primary charged particle beam.

In a typical embodiment, the system includes a charged particle source, a beam delivery system configured to direct the beam along a beam path toward the sample, and a sample holder maintained at ground potential. A control system is provided for switching between an imaging mode and a discharge mode by modulating the accelerating voltage applied to the charged particle source. In the imaging mode, the accelerating voltage is set to a first value such that the beam reaches the sample with a non-zero landing energy suitable for generating imaging signals. In the discharge mode, the accelerating voltage is reduced to a second value such that the beam reaches the sample with a landing energy approximately equal to zero electron volts. This low-energy condition enables controlled neutralization of accumulated surface charge.

The modulation of beam energy is achieved by varying the accelerating voltage applied to the source, rather than by adjusting a retarding potential applied to the sample or surrounding electrodes. This configuration allows the sample to remain at ground potential throughout operation. Switching between modes is preferably performed without adjusting the state of the beam-forming or focusing lenses, enabling rapid and consistent transition between imaging and charge neutralization without requiring optical realignment.

As a consequence of the reduced beam energy in the discharge mode, the charged particle beam undergoes increased divergence in the region adjacent the sample. This divergence facilitates neutralization of charge over a spatially extended region of the sample surface, beyond the narrow footprint typically associated with high-resolution imaging beams. In this way, the invention enables efficient, self-limiting charge control in systems employing low landing energy beams for imaging, including those operating in the range of approximately 50 to 2000 electron volts.

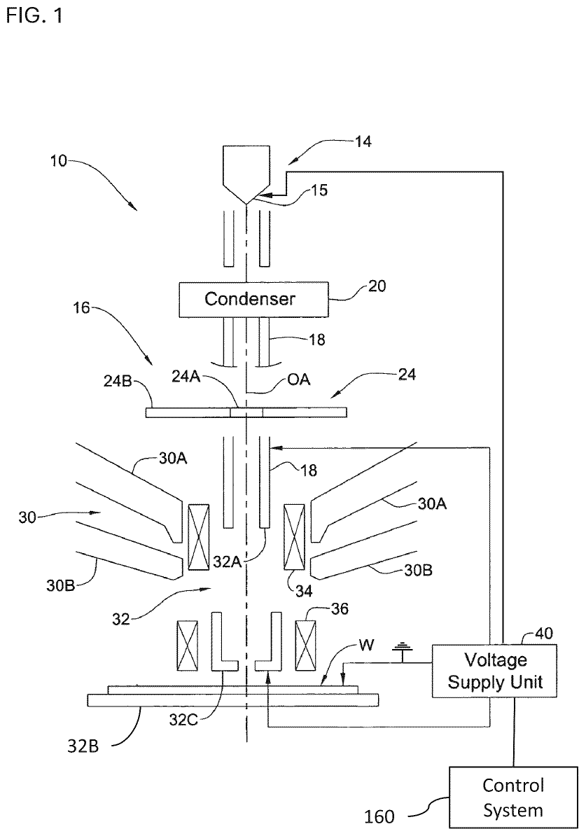

Turning now to the drawings, FIG. 1 schematically illustrates an example of a charged particle beam apparatus 10 according to an embodiment of the invention. The apparatus is configured for imaging a sample and neutralizing charge accumulated on the sample surface. The structure shown is representative of a scanning electron microscope (SEM) or charged particle beam inspection system, though the invention is not limited to any particular platform configuration.

The apparatus 10 includes a charged particle beam source 14 (e.g., an electron gun) having an electron-emitting cathode 15. The cathode 15 is supplied with an accelerating voltage by a voltage supply unit 40. A control system 160 is operatively connected to the voltage supply unit 40 and configured to modulate the accelerating voltage applied to the cathode 15 in order to switch the system between an imaging mode and a discharge mode, as described further below.

In the non-limiting exemplary architecture illustrated here, the beam emitted from the source 14 propagates along an optical axis OA defined by an anode tube 18 that forms part of the beam column 16. The column 16 typically further includes a condenser lens arrangement 20 and a focusing arrangement 22. The focusing arrangement 22 in this non-limiting example is a compound lens system that includes a magnetic objective lens 30 and an electrostatic immersion lens 32 located downstream of the magnetic lens 30 with respect to the direction of beam propagation.

In this example, the magnetic objective lens 30 is formed by two pole pieces 30A and 30B defining a magnetic lens gap. The immersion lens 32 includes three electrodes: a first electrode 32A constituted by the lower end of the anode tube 18, a second electrode 32B which, in this example, is constituted by the sample itself (here labelled by way of example as “wafer W”), and a third “cap” electrode 32C located between the first and second electrodes to regulate the electric field in the region adjacent the sample. In the illustrated embodiment, the wafer 32B is held at ground potential, while the cap electrode 32C and the anode 18 may be biased according to operational requirements.

The beam column may also include deflection elements to direct and align the beam. In the illustrated example, a first deflector 34 is mounted within the magnetic lens gap, and a second deflector 36 is positioned within the field generated by the immersion lens 32. The deflectors may be magnetic or electrostatic and may be configured to perform both fixed and dynamic deflection functions, including beam alignment and scanning.

The system further includes a detector 24 for collecting secondary electrons emitted from the sample during imaging. In this example, the detector 24 is of the in-column type, with a plate-shaped body having an opening 24A aligned with the optical axis OA and a surrounding detection region 24B. Other types of detectors may also be used.

The voltage supply unit 40 is operated under control of the control system 160 to vary the potential of the cathode 15 and thereby adjust the energy of the charged particle beam. In the imaging mode, the beam is accelerated to a first energy level suitable for producing high-resolution image signals upon interaction with the sample. In the discharge mode, the accelerating voltage is reduced such that the beam reaches the sample with a landing energy approximately equal to zero electron volts. Preferably, the switching between these modes is performed without adjustment to the state of the beam-forming or focusing elements of the column.

The configuration shown in FIG. 1 enables the system to operate in both imaging and discharge modes while maintaining the sample at ground potential. This simplifies system integration and supports efficient, self-regulating charge neutralization, as described further below. The configuration shown in FIG. 1 enables the system to operate in both imaging and discharge modes while maintaining the sample at ground potential. Although not required in the illustrated embodiment, a retarding electrode may optionally be included proximate the sample and biased to assist in beam deceleration; however, any such retarding potential is preferably held constant during switching between modes.

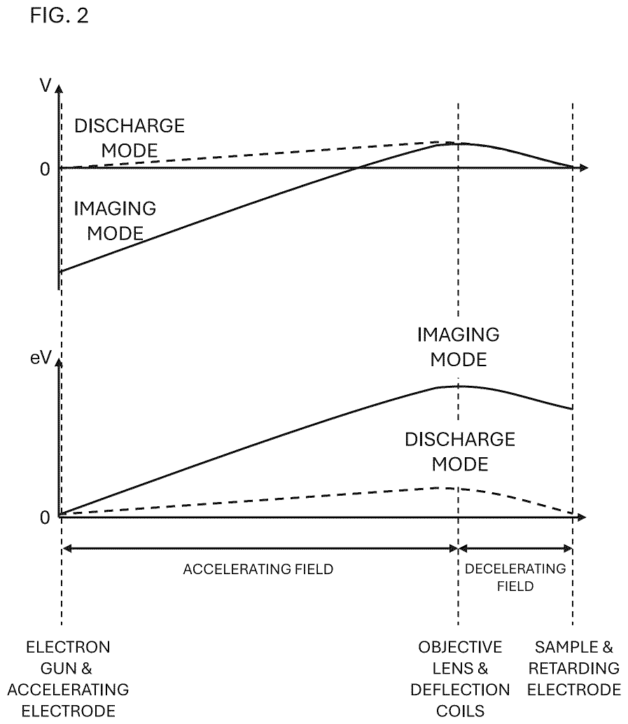

Switching between the imaging and discharge modes in the present invention is achieved by modulating the accelerating voltage applied to the charged particle source, and preferably without altering the electrostatic environment downstream of the source. FIG. 2 illustrates this relationship by showing two aligned graphs that schematically represent the electric potential and the corresponding electron energy along the beam axis during each mode of operation.

In the upper graph of FIG. 2, electric potential is plotted as a function of position along the beam path from the source to the sample. Two curves are shown: a solid line representing the imaging mode, and a dashed line representing the discharge mode. In the imaging mode, the cathode is held at a high negative potential and the potential rises approximately linearly to a maximum value near the objective lens, where the lens and deflection coils are located. Downstream of this point, the potential decreases to zero at the sample, which is held at ground. In the discharge mode, the cathode is biased near ground, and the potential rises gently from the source to the same maximum value at the objective lens. From that point onward, the discharge mode potential curve coincides with that of the imaging mode, decreasing to zero at the sample.

The identical terminal segment of the potential curves demonstrates that the field conditions in the vicinity of the sample remain unchanged during switching, and that the entire variation in beam energy is effected by adjusting the voltage of the source. No change is made to the state of the beam-forming or focusing elements, and the sample remains at ground potential. A vertical dashed line aligned across both graphs indicates the location of the objective lens and deflection system, at which point the potential reaches its peak. It will be noted that the plots shown here are schematic for clarity of presentation, and that the actual variations in potential may not be linear and/or smooth as shown, depending on details of the implementation of the various lens system components.

The lower graph in FIG. 2 shows the corresponding electron energy along the beam axis in each mode. In both modes, the electron energy starts from zero at the emission point and increases along the beam path due to acceleration through the electric field. In the imaging mode, the beam energy increases steeply to a maximum at the objective lens, and then decreases slightly due to deceleration before reaching the sample with a substantial positive landing energy. In the discharge mode, the beam energy increases gradually to a much lower peak value at the objective lens, and then decreases back to approximately zero at the sample. The discharge beam thus arrives at the sample with near-zero kinetic energy, suitable for controlled neutralization of surface charge.

The pair of graphs in FIG. 2 illustrates that the switching between imaging and discharge modes is effected solely by changing the accelerating voltage applied to the source, without modifying the potential of the sample or the configuration of downstream optical elements. Since the electron source and/or associated electrode is typically a small component with relatively low capacitance, this approach allows mode switching to be performed rapidly and consistently, while maintaining beam alignment and field stability in the region of the sample.

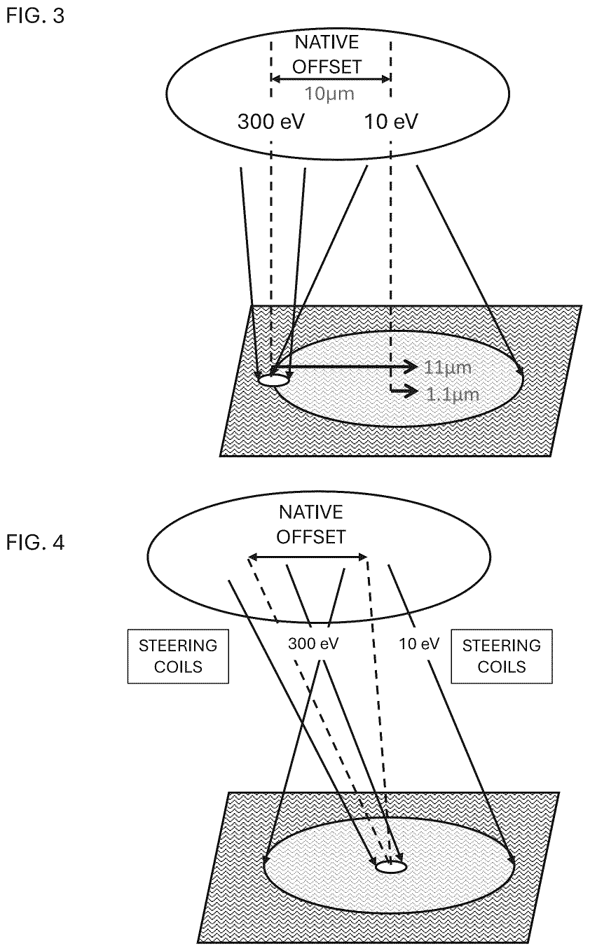

FIG. 3 illustrates, in a schematic isometric view, the differing behavior of charged particle beams at two energy levels as they propagate through an objective lens toward a sample surface. Two beams are shown: one representing a high-energy imaging beam and the other a low-energy discharge beam. The optical paths of the beams are indicated by dashed lines, and their respective envelopes are represented by conical outlines terminating in circular footprints (“spots”) on the surface of the sample.

The higher-energy beam, labeled as operating at 300 eV in this example, is shown as a converging cone that forms a tightly focused, small-diameter spot on the sample surface. This beam is representative of the imaging mode of operation, in which the charged particle beam is focused by the objective lens to achieve high spatial resolution.

By contrast, the lower-energy beam, labeled as operating at 10 eV, is shown as a diverging cone that forms a significantly larger spot on the sample surface. This beam is representative of the discharge mode, in which the energy of the beam is reduced by lowering the accelerating voltage applied to the source. As a result of the lower beam energy, the optical response of the column changes: the beam experiences reduced focusing effectiveness and increased susceptibility to lens aberrations, resulting in a broader divergence angle. This divergence causes the beam to spread laterally in the region adjacent the sample, creating a spatially extended area of interaction.

The broader footprint of the low-energy beam enables charge neutralization over a larger area of the sample surface, in contrast to the localized interaction region of the imaging beam. In some implementations, the discharge spot may be substantially larger than the imaging spot, and the imaging spot may be entirely contained within the area covered by the discharge beam. In the example shown, the imaging beam overlaps only the periphery of the discharge beam, but this relationship may vary between implementations.

Also illustrated in FIG. 3 is an example of a lateral offset between the optical axes of the two beams. This offset, labeled as 10 μm, represents a practical effect that may arise from mechanical misalignments in the lens system. While ideally both beams would share a common optical axis, in practice such offsets are frequently observed. The landing positions of the beams on the sample are also laterally displaced as a result.

In some cases, where the offset is small and the extent of spreading of the beam in discharge mode is sufficient to cover the current location of the imaging mode beam, or where the discharge beam spot follows closely behind the imaging beam spot due to a scanning motion, the offset may not require correction. In some cases, however, it may be preferred to apply a correction to bring the two beams into alignment, or at least to reduce an extent of the offset during use.

Since the imaging beam and the discharge beam are not operated simultaneously, one approach to compensating for such an offset would be to adjust a corrective beam steering input to one or both of the beams to align one beam with the other, or to align both with a nominal center point of the column. However, this would typically require switching of a steering arrangement at each transition between the imaging mode and the discharge mode, which would likely increase the time it would take to switch between modes and may slow down overall operation of the system.

An alternative and preferred approach takes advantage of the differential response of the different energy beams to a beam steering arrangement. Since the higher-energy beam is deflected more strongly than the lower-energy beam, it is possible to find a compensatory deflection input which will bring the two beams into alignment. In the non-limiting example of FIG. 3, this is shown as arrows illustrating that, at a certain level of deflection input, the 300 eV beam is deflected by 11 μm while the 10 eV beam is deflected by 1.1 μm. This would bring the two beams'landing locations into alignment, resulting in concentric spots on the sample surface.

FIG. 4 illustrates the result of this correction strategy compensating for the offset of FIG. 3. In this example, the same optical arrangement is shown, now supplemented with a pair of steering coils positioned on opposite sides of the beam paths. A common deflection field is applied to both beams. Due to their differing energies, the deflection produces a larger lateral shift in the high-energy beam than in the low-energy beam. By selecting an appropriate fixed deflection value, the landing positions of the two beams can be brought into alignment, resulting in concentric beam footprints on the sample surface. This compensation strategy requires no dynamic adjustment during mode switching, thereby avoiding any impact on speed of operation.

The deflection elements shown in FIG. 4 may be implemented using conventional final shift or beam steering coils, and may be configured to superimpose both fixed offsets and dynamic scanning patterns as needed. The correction described here is compatible with other forms of beam control and allows the discharge beam to be aligned with the imaging beam despite native optical or mechanical offsets between their respective trajectories.

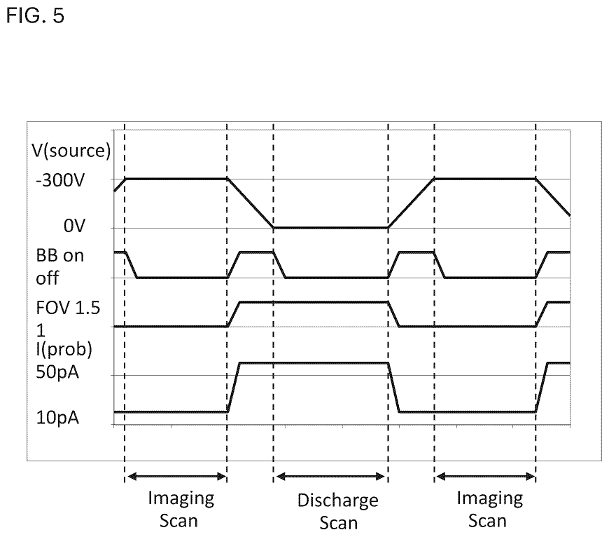

FIG. 5 illustrates an example of the timing relationships between various system parameters during operation of the apparatus in imaging and discharge modes. The diagram shows four vertically stacked plots sharing a common time axis, representing successive operating periods including an imaging scan, a transition interval, a discharge scan, a second transition, and a return to imaging. The transitions are delineated by vertical dashed lines. The relative durations of these periods are illustrative only, and in practice may be selected or adjusted based on sample properties, operating conditions, or performance criteria. Most preferably, prior to starting imaging of a given sample type, details of the sample are pre-processed to determine optimal imaging parameters, predicted charge build-up resulting from those parameters, and appropriate charge-control parameters for neutralizing that charge build-up. These parameters can typically then be used during inspection of all samples of that type. Optionally, real-time image quality analysis may be used to assess the efficacy of the discharge mode operation and the operating parameters may be varied accordingly.

The first plot in FIG. 5, labeled “V(source),” represents the accelerating voltage applied to the electron source (cathode). This voltage directly determines the energy gained by electrons as they travel through the column. In the imaging scan period, the source is held at a high negative potential (−300 V in the non-limiting illustrated example), resulting in a non-zero landing energy at the sample. During the transition period, the source voltage is ramped linearly toward 0 V, corresponding to the discharge mode in which the landing energy approaches zero.

A second ramp returns the source voltage to its original value prior to the next imaging scan. The transitions are illustrated with diagonal slopes, but may in practice follow any suitable ramp profile optimized for stability or switching speed.

The second plot, labeled “BB,” represents the status of a beam blocker, which is optionally used to suppress delivery of the charged particle beam to the sample during transition periods. In this example, the beam blocker is activated (“on”) during both transition intervals and is deactivated (“off”) during the imaging and discharge scan periods. This prevents partially accelerated electrons from reaching the sample during voltage transitions, ensuring that only well-defined energy distributions are delivered to the surface. The beam blocker is a standard part of a scanning electron microscope and may be implemented in various ways, for example, using a beam blanking deflector or electrostatic gating element positioned in the upper portion of the beam column (e.g., at anode tube 18).

The third plot, labeled “FOV,” represents an optional field-of-view adjustment applied during mode switching. In the illustrated example, the FOV parameter takes a value of “1” during imaging and a value of “1.5” during the discharge scan. This is typically implemented by applying a scaling factor (1.5) to the scan deflection angle, resulting in a broader beam footprint at the sample surface during discharge. This adjustment can enhance the spatial coverage of the low-energy neutralization beam, especially in systems where additional divergence is desired. Because the change is applied rapidly and does not involve refocusing of the beam optics, it remains compatible with fast mode switching and does not compromise the system's ability to maintain imaging alignment.

The fourth plot, labeled I(prob), shows the beam current delivered by the electron gun source. In the illustrated example, a lower current (e.g., 10 pA) is used during the imaging scan, while a higher current (e.g., 50 pA) is used during the discharge scan. The current used during imaging is chosen according to the conditions expected to be optimal for imaging the particular sample. The option of increasing the current during discharge allows for more efficient neutralization of accumulated surface charge and thus shortening of the period required for discharge. The transition in current is shown to occur at the start of each transition period, ensuring that the beam is stabilized before reaching the sample. The ability to adjust probe current dynamically between modes may be implemented via source extraction voltage, condenser lens excitation, or other beam current control mechanisms.

The relative duration of imaging and discharge scans, as well as the length of the transitions, may be determined based on various operational factors. These include the extent to which the sample is expected to accumulate surface charge under the imaging beam, the material and geometric properties of the sample surface, and the degree of neutralization required to maintain stable imaging conditions. In some implementations, scan durations may be fixed, while in others they may be adjusted dynamically in response to observed changes in image quality, charge contrast effects, or other system feedback signals.

All of the above control signals are preferably generated by common timing logic circuitry that is integrated with control system 160, all as is known in the art. The coordinated timing illustrated in FIG. 5 enables rapid alternation between imaging and discharge modes without loss of beam stability or image registration, and supports integration with continuous scanning strategies such as scanning frame averaging (SFA), as discussed further below.

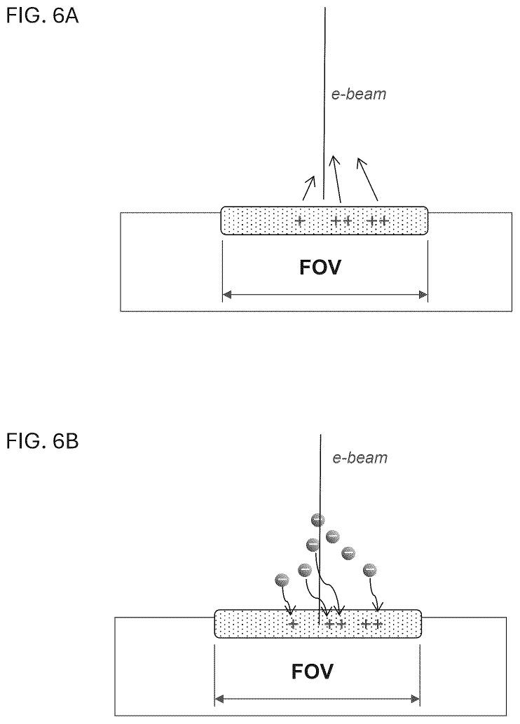

FIGS. 6A and 6B schematically illustrate the respective effects of imaging and discharge modes on the surface charge condition of a sample. These figures are side views showing a portion of the sample surface under the field of view (FOV) of the charged particle beam, with simplified representations of beam interaction and charge behavior.

FIG. 6A depicts the imaging mode. The charged particle beam, delivered at a relatively high landing energy (e.g., 50-1500 eV), interacts with the sample surface to generate secondary electrons and other image-forming signals. The field of view of the beam is indicated schematically by the lateral width of the region marked “FOV.” Arrows emerging from the sample surface represent the ejection of secondary electrons, which leads to a net accumulation of positive surface charge. This residual charging is illustrated by multiple localized “+” symbols on or near the surface. The magnitude and spatial distribution of the accumulated charge may vary depending on the material properties, beam energy, current, and exposure time. In insulating or partially insulating materials, this charge can persist and progressively degrade image quality or distort beam landing characteristics in successive scans.

FIG. 6B illustrates the discharge mode, applied to the same sample region. In this mode, the beam energy is reduced to near-zero landing energy, and the beam forms a spatially extended cloud of low-energy electrons, illustrated as small circles marked with “−” signs. These electrons hover near the surface due to their low kinetic energy and are influenced by local electrostatic fields. Arrows directed from the electron cloud toward the surface represent the attraction of electrons to positively charged regions. This targeted neutralization allows accumulated positive charge to be dissipated efficiently and selectively, while negatively charged or neutral regions are largely unaffected. The self-limiting nature of this mechanism helps preserve surface stability without requiring detailed knowledge of the charge distribution or closed-loop feedback.

The two figures together illustrate the alternating sequence of operation described in earlier sections: a beam with imaging energy is used to acquire high-resolution data, resulting in local positive charging, and is followed by a neutralizing low-energy beam that spreads across the field of view and selectively discharges those same areas. This alternating mode of operation allows high-resolution imaging to be maintained over time, even on challenging materials, without requiring a conductive coating or external charge control system.

We now turn to various optional implementation features and architectural variants that may be used to implement the system and method described herein. These features are not essential but may provide additional functionality or performance advantages in specific applications, or provide practical examples of implementations to support certain optional features referred to above.

As noted in the description of FIG. 2, switching between imaging and discharge modes is preferably performed by modulating the accelerating voltage applied to the charged particle source. In many implementations, this voltage is applied to a small, low-capacitance electrode associated with the source assembly, such as a Wehnelt electrode or an emitter bias terminal. The relatively low capacitance of such components enables fast voltage transitions, supporting mode switching within time intervals on the order of tens of microseconds, without requiring adjustment of column optics or retuning of imaging parameters.

Although the sample is typically held at ground potential, a retarding electrode may optionally be included proximate the sample to assist in beam deceleration or field shaping. This electrode may form part of an electrostatic immersion lens, as in the configuration shown in FIG. 1, and may be biased relative to the anode or cap electrode. In embodiments where a retarding electrode is present, its voltage is preferably held constant during switching between imaging and discharge modes, so that only the source potential is varied.

As described above with reference to FIG. 5, certain system parameters may optionally be modulated between imaging and discharge modes. These include:
Beam gating during transitions, such as by use of a blanking element;
Field-of-view adjustments to influence the beam footprint, achieved, for example, via scan angle, aperture, or lens settings; and
Probe current modulation, which may be implemented through adjustments to the source extraction field or condenser lens configuration.

In systems equipped with a moving stage, the imaging and discharge modes may be applied during continuous sample motion. In such cases, the position of the charged particle beam may be synchronized with the motion of the sample holder to maintain alignment with a target region or to implement a desired scan pattern. Coordination between beam control and stage movement may be used to ensure that both imaging and neutralization occur across the same regions, either sequentially or in an interleaved fashion. Various synchronization strategies may be employed, including fixed timing offsets, overlapping frame-based scanning, or real-time position feedback.

Where continuous scanning is employed, the invention may be integrated with a scanning frame averaging (SFA) approach, in which overlapping frames are acquired and averaged to improve image quality or compensate for motion blur. In such configurations, the timing of the imaging and discharge modes may be aligned with the frame acquisition cycle, and neutralization may be applied to the same region shortly before or after imaging, without interrupting the motion of the stage.

While the invention is described primarily with reference to electron beams, the same principles may be applied in systems that use other types of charged particles, such as ions. In such cases, the low-energy discharge mode may still produce a spatially extended footprint suitable for selective neutralization, although the beam optics and interaction dynamics may differ. Electrons are currently preferred due to their favorable beam properties and non-destructive interaction with most sample surfaces.

Although FIG. 1 shows an in-column detector with a central beam aperture, the invention is compatible with a wide range of detector types and geometries. These may include Everhart-Thornley detectors, annular backscatter detectors, or energy-filtered detectors, depending on the imaging requirements of the application. The switching and discharge strategy described herein may be implemented independently of the specific detection configuration.

It will be appreciated that the above descriptions are intended only to serve as examples, and that many other embodiments are possible within the scope of the present invention as defined in the appended claims.

What is claimed is:

1. A method of operating a charged particle beam apparatus for imaging a sample and neutralizing charge accumulated on the sample, the method comprising:
(a) generating a charged particle beam using a charged particle source supplied with an accelerating voltage;
(b) directing the charged particle beam along a beam path through one or more beam-forming or focusing elements toward the sample, wherein the sample is positioned on a sample holder maintained at ground potential;
(c) operating the apparatus in an imaging mode in which the accelerating voltage is set to a first value such that the charged particle beam reaches the sample with a non-zero landing energy suitable for imaging; and
(d) switching the apparatus from the imaging mode to a discharge mode by reducing the accelerating voltage to a second value such that the charged particle beam reaches the sample with a landing energy approximately equal to zero electron volts, thereby enabling charge neutralization,
wherein, due to the reduced accelerating voltage in the discharge mode, the charged particle beam diverges in a region adjacent the sample such that a spatially extended area of the sample surface is exposed to the low-energy charged particles for charge neutralization.

2. The method of claim 1, wherein the accelerating voltage is modulated by adjusting a potential applied to an electrode of the charged particle source, the electrode having a low capacitance relative to the sample holder.

3. The method of claim 2, wherein the electrode forms part of the charged particle source assembly.

4. The method of claim 1, further comprising applying a retarding voltage to an electrode located proximate the sample to decelerate the charged particle beam, wherein the retarding voltage remains constant during switching between the imaging mode and the discharge mode.

5. The method of claim 1, wherein the charged particle beam comprises electrons and the landing energy in the discharge mode is sufficiently close to zero electron volts that the electrons are reflected from regions of the sample having a local negative surface potential while being attracted to regions of the sample having a local positive surface potential, thereby neutralize accumulated positive charge.

6. The method of claim 1, wherein reducing the accelerating voltage in the discharge mode causes the beam to experience increased divergence near the sample surface, thereby achieving spatially distributed charge neutralization over a region greater than an imaging mode beam spot size.

7. The method of claim 6, wherein the beam path during the discharge mode is laterally offset from the beam path during the imaging mode, and the divergence of the beam in the discharge mode is sufficient to cause overlap of the neutralization region with the imaging location.

8. The method of claim 1, further comprising modulating a beam deflection element in coordination with switching between the imaging mode and the discharge mode so as to maintain alignment of the beam landing position on the sample.

9. The method of claim 8, wherein the beam deflection element comprises a final shift or beam steering unit located proximate the sample.

10. The method of claim 1, further comprising applying a fixed deflection offset to the charged particle beam path, wherein a native energy-dependent difference in beam landing position is compensated by the energy-dependent sensitivity of a beam deflection element.

11. The method of claim 1, further comprising moving the sample holder continuously during operation of the apparatus, and performing switching between the imaging mode and the discharge mode during such motion.

12. The method of claim 11, wherein the position of the charged particle beam is manipulated in synchronization with the movement of the sample holder to provide spatially distributed charge neutralization.

13. The method of claim 11, further comprising acquiring image data using a scanning frame averaging process that combines image data from overlapping regions to compensate for motion of the sample holder.

14. The method of claim 1, wherein switching between the imaging mode and the discharge mode is performed by modulating the accelerating voltage within a time period of less than 100 microseconds, without requiring refocusing of the charged particle beam.

15. A charged particle beam apparatus for imaging a sample and neutralizing charge accumulated on the sample, the apparatus comprising:
(a) a charged particle source configured to emit a charged particle beam and to receive an accelerating voltage to control the energy of the emitted beam;
(b) a beam delivery system configured to direct the charged particle beam along a beam path through one or more beam-forming or focusing elements toward the sample;
(c) a sample holder configured to support the sample and to be maintained at ground potential during operation in the imaging and discharge modes; and
(d) a control system configured to switch between an imaging mode, in which the accelerating voltage is set to a first value such that the charged particle beam reaches the sample with a non-zero landing energy suitable for imaging, and a discharge mode, in which the accelerating voltage is set to a second value such that the charged particle beam reaches the sample with a landing energy approximately equal to zero electron volts to enable charge neutralization,
wherein, due to the reduced accelerating voltage in the discharge mode, the charged particle beam diverges in a region adjacent the sample such that a spatially extended area of the sample surface is exposed to the low-energy charged particles for charge neutralization.

16. The apparatus of claim 15, wherein the charged particle source comprises an electrode forming part of a source assembly, and the control system is configured to apply the accelerating voltage to the electrode.

17. The apparatus of claim 15, further comprising an electrode located proximate the sample and configured to receive a retarding voltage for decelerating the charged particle beam, wherein the control system is further configured to maintain the retarding voltage constant while switching between the imaging mode and the discharge mode.

18. The apparatus of claim 15, further comprising a beam deflection unit configured to apply a fixed deflection offset, wherein a native energy-dependent difference in beam landing position between the imaging mode and the discharge mode is compensated by the energy-dependent deflection sensitivity of the beam deflection unit.

19. The apparatus of claim 15, further comprising a translation stage configured to move the sample holder continuously during operation, wherein the control system is configured to switch between the imaging mode and the discharge mode during such motion, and wherein the control system is configured to adjust the position of the charged particle beam in synchronization with movement of the sample holder to provide spatially distributed charge neutralization.

20. The apparatus of claim 15, wherein the control system is configured to switch between the imaging mode and the discharge mode by modulating the accelerating voltage within a time period of less than 100 microseconds, without requiring refocusing of the charged particle beam.
